(19) United States
(12) Patent Application Publication
(10) Pub. No.: US 2013/0265775 A1
(43) Pub. Date: Oct. 10, 2013

(54) Supporter for Use During the Overmolding of a Light Engine

(71) Applicant: Glenn Freeman, San Antonio, TX (US)

(72) Inventor: Glenn Freeman, San Antonio, TX (US)

(21) Appl. No.: 13/858,186

(22) Filed: Apr. 8, 2013

Related U.S. Application Data
(60) Provisional application No. 61/621,060, filed on Apr. 6, 2012.

(51) Int. Cl. H05K 13/00; F21V 5/04; F21V 15/01; F21V 21/00

(52) U.S. Cl. CPC H05K 13/0046; F21V 21/00; F21V 5/04; F21V 15/01
USPC 362/311.02; 362/382; 362/375; 248/49; 264/272.14

(57) ABSTRACT

A printed circuit board supporter includes a top surface, a bottom surface and a central portion. The top surface enables location of a printed circuit board. The bottom surface enables the force from an injection mold to be distributed across the bottom of the printed circuit board. The central portion of the printed circuit board supporter contains force spreading columns which pass between the top surface of the printed circuit board supporter and the bottom surface of the printed circuit board supporter.

### CROSS REFERENCE TO RELATED APPLICATIONS

This application claims the benefit of Provisional U.S. Patent Application No. 61/621,060 filed Apr. 6, 2012.

### STATEMENT REGARDING FEDERALLY FUNDED RESEARCH AND DEVELOPMENT

The invention described in this patent application was not the subject of federally sponsored research or development.

### FIELD

The present invention relates to overmolded LED light engines; more particularly the present invention relates to the manufacture and construction of overmolded LED light engines such as overmolded LED light engines used to illuminate signs identifying businesses and for accenting both interior and exterior architectural designs.

### BACKGROUND

As the use of light sources has evolved from incandescent lamps to fluorescent lamps to LEDs, so too have the devices evolved that are used to position LEDs to provide the needed illumination. These positioning devices and the LEDs mounted therein are called LED light engines. Most LED light engines utilize some type of overmolded plastic sealant to protect the light engine and to enable its utilization. To assure proper operation of an LED light engine, the parts within the light engine which are encapsulated in sealant during an overmolding process must be kept in their designated positions.

Prior art solutions to the problem of holding all the parts of an LED light engine in position during the overmolding process have included the use of a variety of different pins or positioning devices located within the mold. The creation of molds including such pins or positioning devices is complex and therefore expensive. In addition, the pins or positioning devices are subject to wear or breakage thus shortening the usable life of the mold.

There is therefore a need in the art for an inexpensive and reliable system which assures that the internal components within an LED light engine stay in their designated positions during the overmolding process.

### SUMMARY

The present invention provides an inexpensive and reliable system which causes that the internal components within an LED light engine stay in their designated positions during the overmolding process. The present invention is enabled by a printed circuit board supporter.

The printed circuit board supporter of the present invention has three operative portions. These three operative portions are its top surface, its bottom surface and a central portion positioned therebetween.

The top surface of the printed circuit board supporter enables the positioning of a printed circuit board thereon. Such positioning is accomplished by engagement of mechanical placement means on the top surface of the printed circuit board supporter which engage openings or holes formed in the bottom surface of the printed circuit board.

The bottom surface of the printed circuit board supporter provides the contact area for when the combination of the printed circuit board supporter and the printed circuit board is placed in a mold over an LED cover member, an LED lens member, or a flexible web member for overmolding.

The central portion of the printed circuit board supporter includes force spreading columns which work to hold the printed circuit board in place during the overmolding process. In addition, the central portion of the printed circuit board supporter includes a channel. This channel both guides and positions the insulated wires which are attached to the bottom of the printed circuit board to provide electrical energy thereto.

The printed circuit board is pinched between an LED cover member, an LED lens member or a flexible web member and the printed circuit board supporter during the overmolding process. Thus, when the mold is closed and the molten sealant material flows into the mold, the printed circuit board and the LEDs mounted thereon are restrained from movement. In the illustrated embodiment, when the printed circuit board, the printed circuit board supporter and the lens member are removed from the mold, they are both held together and partially covered by the sealant material. In addition, the sealant material holds the insulated wires in place, provides a moisture barrier, and acts as a stress relief for the wires.

### BRIEF DESCRIPTION OF THE DRAWING FIGURES

A better understanding of the printed circuit board supporter and its method of use may be had by reference to the drawing figures wherein:

FIG. 1 is an exploded perspective view of the components within a light engine; more particularly, a schematic representation of a flexible LED cover member, a schematic representation of a printed circuit board and the printed circuit board supporter of the present invention;

FIG. 2A is a left side perspective of the top of the printed circuit board supporter;

FIG. 2B is a left-side perspective view of the bottom of the printed circuit board supporter shown in FIG. 2A;

FIG. 3A is a front elevational view in partial section of the printed circuit board supporter in use during the overmolding step in the manufacture of the light engine wherein a flexible LED lens member is placed over the LEDs;

FIG. 3B is a left end elevational view in partial section of the printed circuit board supporter in use during the overmolding step in the manufacture of a light engine wherein a flexible LED lens member is placed over the LEDs; and

FIG. 4 is a left end elevational view in partial section of a light engine prior to its connection to a sign wall using a threaded fastener.

### DESCRIPTION OF THE EMBODIMENTS

As explained above in the BACKGROUND portion of this patent application, the present invention is used in a light engine. Within the light engine are the LEDs which emit the light to illuminate a surface such as a translucent panel in a sign or to highlight portions of either interior or exterior architectural designs. The LEDs are mounted on a printed circuit board to provide the electrical energy to the LEDs for transformation into light energy. Placed over the LEDs is a flexible LED cover member, a flexible LED lens member or a flexible web member. The covers and the lenses which are positioned over the LEDs are typically interconnected by a web to form a single piece. Light engines are then typically overmolded to both protect the light engine and to hold the components within the light engine together.

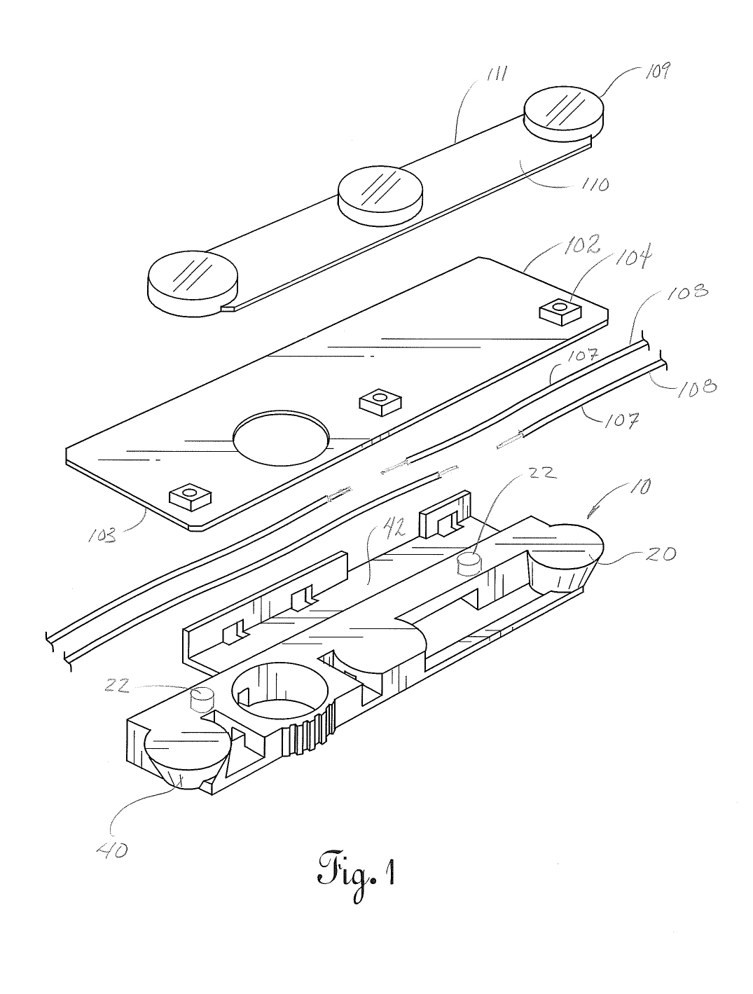

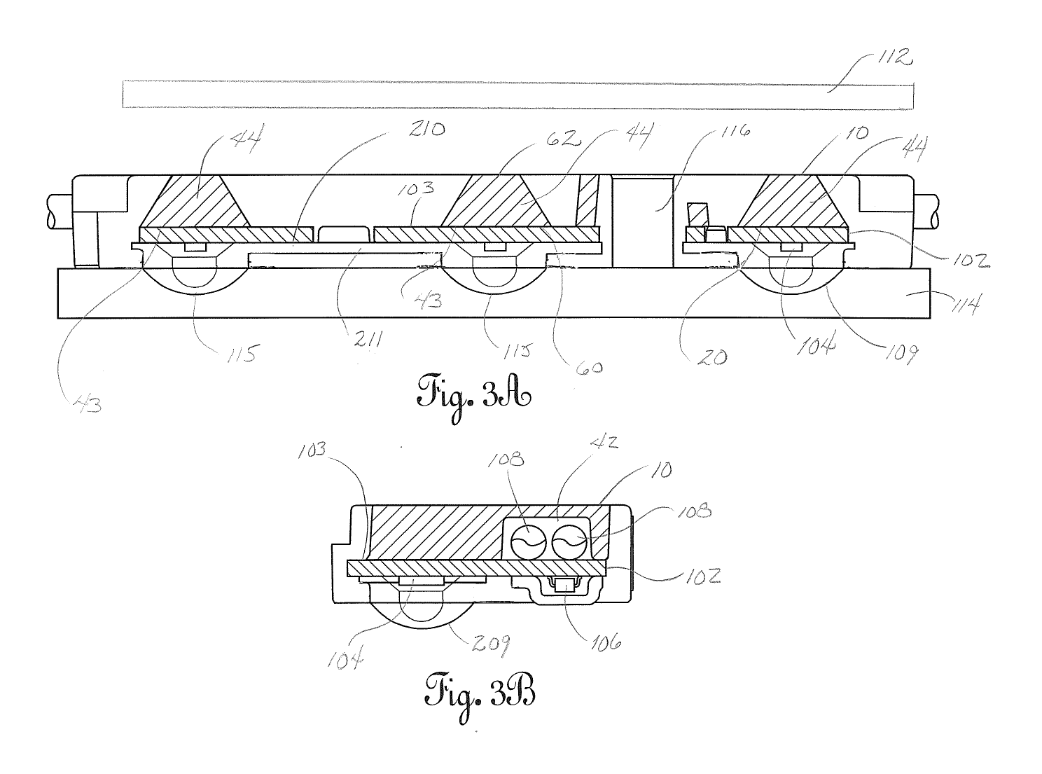

Shown in FIG. 1 are the components within a light engine made using the printed circuit board supporter 10 of the present invention. Three LEDs 104 are shown on the printed circuit board 102 shown in FIG. 1; however, those of ordinary skill in the art will understand that any number of LEDs from a single LED to multiple LEDs may be mounted on the printed circuit board 102. The electrical componentry 106 (FIG. 3B) on the printed circuit board 102 transforms the electrical energy from a power source to the electrical energy suitable to illuminate the LED 104; for example, 12 volt direct current or 12 volt pulsating direct current.

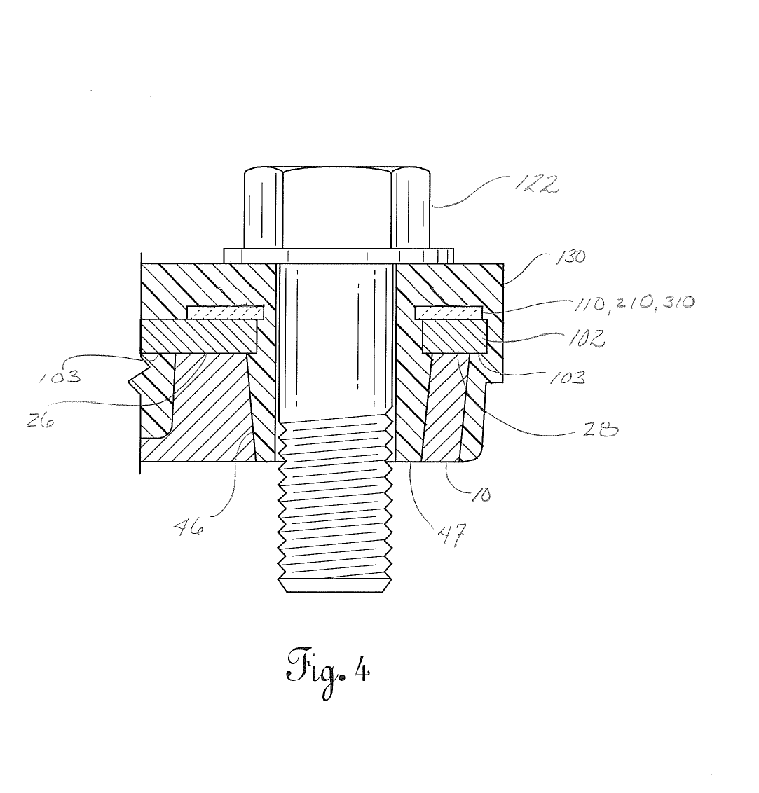

Placed over the LEDs 104 on the printed circuit board 102, as shown in FIG. 1, are substantially cylindrical LED covers 109. These LED covers are connected one to another with a web 111 to form an LED cover member 110. Alternatively, and as shown in FIG. 3A and FIG. 3B, an LED lens 209 may be used instead of an LED cover 109. When the LEDs lenses 209 are connected one to another using a web 211, they become an LED lens member 210. In some situations, a user may want to leave the LED 104 uncovered or unlensed, thereby relying on the encapsulant over the LED for protection or for modification of an emitted light ray pattern or both. In such cases, a substantially flat flexible web member 310 (FIG. 4) including one or more openings or holes constructed and arranged to surround each LED may be used.

As further shown in FIG. 1, a supporter 10 for the printed circuit board 102 is located under the printed circuit board 102. The utility of printed circuit board supporter 10 of the present invention will be explained in detail below, but its key function is to hold the components within the light engine in place during the overmolding process. This is accomplished by locating the printed circuit board 102 with respect to the printed circuit board supporter 10 then pinching the printed circuit board 102 between the printed circuit board 102 and either an LED cover member 110, an LED lens member 210, or a flexible web member 310 when the mold is closed.

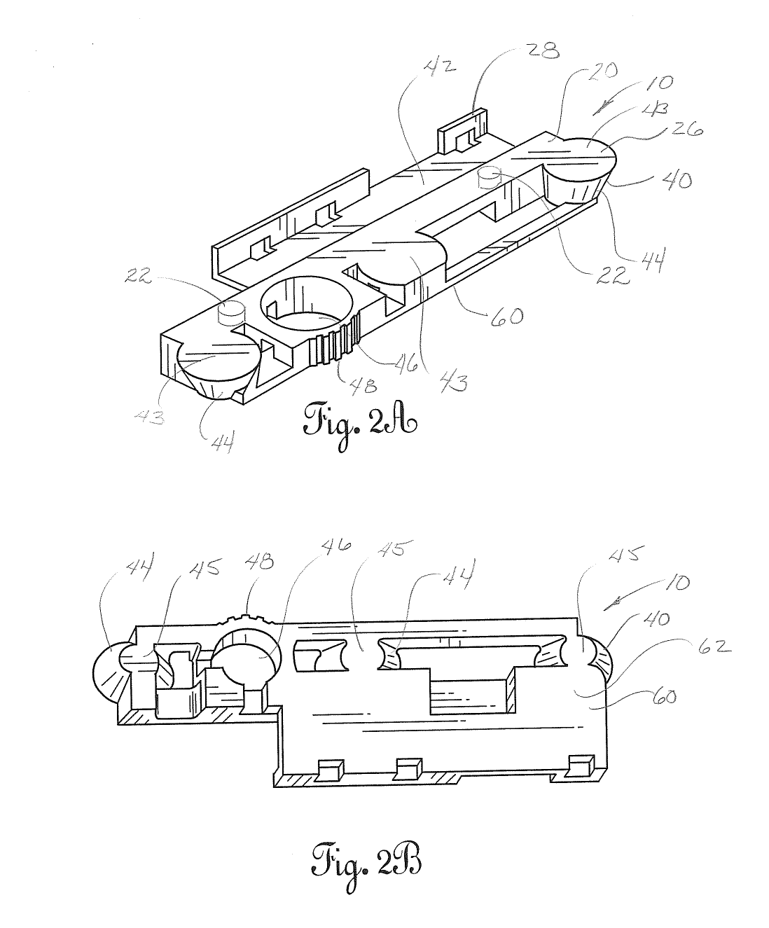

A still better understanding of the printed circuit board supporter 10 of the present invention may be had by reference to FIG. 2A and FIG. 2B. Therein it may be seen that the printed circuit board supporter 10 has a top surface 20, a bottom surface 60, and a central portion 40 formed therebetween.

The top surface 20 has two sections 26, 28. The larger section 26 of the top surface 20 which appears on the front side of FIG. 2A is formed to make contact with the bottom surface 103 of the printed circuit board 102. The smaller section 28 of the top surface 20, which is nearest the back side of the top surface 20, is also formed to make contact with the bottom surface 103 of the printed circuit board 102. The larger section 26 and smaller section 28 of the top surface 20 are co-planar. The sectional view in FIG. 4 shows the co-planarity of the larger section 26 and smaller section 28 of the top surface 20 of the printed circuit board supporter 10.

Also located on the top surface 20 are mechanical placement means 22 for positioning the printed circuit board supporter 10 with respect to the printed circuit board 102. In the preferred embodiment, these mechanical placement means 22 are two substantially cylindrical pins constructed and arranged to fit into substantially cylindrical holes or openings formed in the printed circuit board 102. Alternatively, a single substantially cylindrical hole or opening in the printed circuit board 102 may be used if the second substantially cylindrical pin is placed within an elongated slot or opening formed in the printed circuit board 102. Alternatively, in place of the second cylindrical pin a tab may be used. If a tab is used, the tab is constructed and arranged to fit with an elongated slot or opening formed in the printed circuit board 102. Those of ordinary skill in the art will understand that more than two mechanical placement means 22 may be used.

As may be seen in FIG. 2B the bottom surface 60 of the printed circuit board supporter 10 includes a contact area 62 onto which force from the mold is applied. The utility of the bottom surface 60 of the printed circuit board supporter 10 will become more apparent below in the description of the use of the printed circuit board supporter 10 during the molding process.

The central portion 40 of the printed circuit board supporter 10 includes several key features. The first key feature is the channel 42 for placement of the insulated wires 108 which supply electrical energy to the printed circuit board 102. The channel 42 appears in FIG. 2A as being positioned between the larger section 26 and smaller section 28 of the top surface 20 of the printed circuit board supporter 10. FIG. 3B illustrates how the insulated wires 108 are positioned within the channel 42.

The second key feature in the central portion of the printed circuit board supporter 10 is the force spreading columns 44. These force spreading columns 44 receive force from the top 112 of the mold on the end 45 shown on the bottom of the printed circuit board supporter 10 in FIG. 2B. The force per unit area from the mold is reduced as the area of the force spreading column 44 at the opposite end 43 shown in FIG. 2B because this area is larger. While three generally conical faceted columns 44 are shown in the preferred embodiment, those of ordinary skill will understand that one or more force spreading columns 44 having any suitable cross-section may be used.

Also included within the central portion 40 of the printed circuit board supporter 10 is an optional hole 46. As may be seen in FIG. 4, this optional hole 46 may be used to make a passage for a threaded fastener 122 to attach the completed light engine to a surface such as the inner wall of a sign. As may be seen in FIG. 2A and in FIG. 2B, the outer wall of the optional hole 46 includes a series of ribs 48. These ribs 48 add strength to the outer wall of the optional hole 46 and provide additional contact area for the sealant with the side of the printed circuit board supporter 10.

FIG. 3A and FIG. 3B show how the printed circuit board supporter 10 is used during the overmolding process. The overmolding process begins by placing the cover portion 109 of an LED cover member 110, the lens portion 209 of an LED lens member 210 into sockets 115 formed in the lower portion of the mold 114. Those of ordinary skill in the art will understand that when a flexible web member 310 is used, no sockets 115 are required; however, the flexible web member must be held in position on the mold surface.

The printed circuit board 102 and the printed circuit board supporter 10 are then located with respect to one another using the mechanical placement means 22 described above. Mechanical placement means such as pins formed on the LED cover member 110 mate with openings in the top of the printed circuit board 102 to position the combination of the printed circuit board 102 and printed circuit board supporter 10 to enable the positioning of the LEDs 104 within each cover 109 of the LED cover member 110 within each lens 209 in the LED lens member 210, or within each hole in the flexible web member 310. FIG. 3A shows that the combination of the printed circuit board 102 and the printed circuit board supporter 10 are turned over so that the LEDs 104 point downward, and the bottom surface 103 of the printed circuit board 102 faces upward to engage the top of the mold 112. Those of ordinary skill in the art will understand that if the combination of the three internal components, as shown in FIG. 1, are properly aligned before placement into a mold, the LEDs 104 may be oriented to point upward.

Further shown in FIG. 3A is a cylindrical member 116 which enters the optional hole 46 in the printed circuit board supporter 10. The cylindrical member 116 is smaller than the optional hole 46 formed in the printed circuit board supporter 10. Such difference in size enables the creation of a wall of sealant 47 as shown in FIG. 4.

The positioning of the insulated wires 108 for conveying electrical energy to the printed circuit board 102 within the channel 42 formed in the central portion 40 of the printed circuit board supporter 10 is shown in FIG. 3B. As sealant 130 is allowed to flow into the open space around the insulated wires 108, the combination of the sealant 130 with the insulation 107 around the wires 108 provides two advantages. First, because of the heat of the molten sealant, the molten sealant and the insulation 107 around the wires 108 melt together to form a seal against the entry of moisture. Second, the bond between the sealant and the insulation 107 around the wires 108 acts as a stress relief.

By reading FIG. 3A and FIG. 3B together a person of ordinary skill in the art will understand that the printed circuit board 102 is sandwiched between the printed circuit board supporter 10 and the LED lens member 210. This sandwiching of the printed circuit board 102 between the printed circuit board supporter 10 and the LED lens member 210 holds the printed circuit board 102 and the LEDs 104 positioned thereon in a stable position as the flowing sealant enters the mold and eventually hardens.

FIG. 4 shows a cross section of the optional hole 46 through the printed circuit board supporter 10 after the overmolding process has been completed. The bottom surface 103 of the printed circuit board 102 rests on the top surface 20 of the printed circuit board supporter 10. The LED cover member 110, the LED lens member 210 or the flexible web member 310 is positioned on the top of the printed circuit board 102. Sealant 130 surrounds the printed circuit board 102, the printed circuit board supporter 10 and a portion of the lens member 110. The sealant 130 also forms the optional walled hole 46 through which a threaded fastener 122 or a pop rivet may pass to mount the light engine. While a machine screw with a hexagonal head is shown in FIG. 4, those of ordinary skill will understand that a self tapping screw with one of a variety different heads may be used for mounting the light engine to sheet metal or a wood screw may be used if the light engine is to be mounted on wood.

The plastic materials used for the sealant 130 and the printed circuit board supporter 10 are selected to form a chemical bond with one another during the overmolding process. In addition, the plastic sealant material 130 may provide a moisture barrier where it contacts the LED cover member 110, the LED lens member 210 or the flexible web member 310. Further, the plastic material from which the printed circuit board supporter 10 is made is selected to enable the placement of one side of double-sided tape thereon should such double-sided tape be used to mount a completed light engine against a surface within a sign.

While the disclosed invention has been described according to its preferred and alternate embodiments, those of ordinary skill in the art will understand that still other embodiments will become apparent to those of ordinary skill in the art once having read the foregoing description. Such other embodiments shall be included within the scope and meaning of the appended claims.

What is claimed is:

1. A supporter for a printed circuit board to be included in an LED light engine, said supporter comprising:
a top surface, a central portion and a bottom surface;
said top surface including mechanical placement means for positioning the printed circuit board;
said central portion including a channel for the placement of wires which supply electrical energy to the printed circuit board;
said central portion also including force spreading columns constructed and arranged to apply pressure to the bottom of the printed circuit board;
said bottom surface including a contact area for receiving pressure from a mold section during the overmolding of the LED light engine.

2. The supporter as defined in claim 1 wherein said mechanical placement means includes a plurality of projections extending outwardly from said top surface.

3. The supporter as defined in claim 2 wherein said plurality of projections includes at least one pin and at least one second projection selected from a group including a pin and a tab.

4. The supporter as defined in claim 1 wherein said force spreading columns have a greater surface area at the portion which contacts the printed circuit board than at the portion which contacts the mold section.

5. The supporter as defined in claim 1 further including a screw hole extending between said top surface and said bottom surface.

6. The supporter as defined in claim 5 wherein said screw hole has an outer wall section with a plurality of ribs formed thereon.

7. A light engine comprising:
a printed circuit board having at least one LED mounted thereon, said printed circuit board including the electrical componentry necessary to transform electrical energy into a form usable by said at least one LED, said printed circuit board further being electrically connected to insulated wires supplying said electrical energy to said electrical componentry;
a printed circuit board supporter, said printed circuit board supporter including:
a top surface, a central portion and a bottom surface;
said top surface including mechanical placement means for positioning said printed circuit board;
said central portion including a channel for the placement of insulated wires which supply electrical energy to said printed circuit board;
said central portion also including force spreading columns constructed and arranged to apply pressure to the bottom of said printed circuit board;
said bottom surface including a contact area for receiving pressure from a mold section during the overmolding of the light engine;
overmolded material to hold the light engine together and protect said printed circuit board.

8. The light engine as defined in claim 7 further including an LED cover member or an LED lens member constructed and arranged for placement over said at least one LED.

9. The light engine as defined in claim 8 wherein said mechanical placement means includes a plurality of projections extending outwardly from said top surface.

10. The light engine as defined in claim 8 wherein said plurality of projections includes at least one pin and at least one second projection selected from a group including a pin and a tab.

11. The light engine as defined in claim 8 wherein said force spreading columns in said printed circuit board supporter have a greater surface area at the portion which contacts the printed circuit board than at the portion which contacts the mold section.

12. The light engine as defined in claim 8 further including a screw hole extending between said top surface and said bottom surface.

13. The light engine as defined in claim 12 wherein said screw hole has an outer wall with a plurality of ribs formed thereon.

14. The light engine as defined in claim 8 wherein said overmolded material is a plastic which melts together with the insulation on said insulated wire during the molding process and forms a chemical bond with said printed circuit board supporter, and a seal with either said LED cover member or said LED lens member.

15. A process for manufacturing a light engine comprising:
placing the cover portion of an LED cover member into sockets located in a mold bottom;
affixing a printed circuit board with at least one LED mounted thereon and insulated wires attached thereto to a printed circuit board supporter;
placing the combination of said printed circuit with at least one LED mounted thereon and said printed circuit board supporter onto said LED cover member so that said at least one LED is located within said LED cover portion of said LED cover member;
placing a mold top onto said mold bottom;
injecting sealant material into spaces between said mold top and said mold bottom not occupied by said printed circuit board, said printed circuit board supporter and said LED cover member;
separating said mold top from said mold bottom;
removing said printed circuit board, said printed circuit board supporter and said lens member now partially enclosed by said sealant material from between said mold top and said mold bottom.

16. The process as defined in claim 15 wherein said printed circuit board supporter includes:
a top surface, a central portion and a bottom surface;
said top surface including mechanical placement means for positioning said printed circuit board;
said central portion including a channel for the placement of insulated wires which supply electrical energy to said printed circuit board;
said central portion further including force spreading columns constructed and arranged to apply pressure to the bottom of the printed circuit board;
said bottom surface including a contact area for receiving pressure from said mold top during the overmolding of the LED light engine.

17. The process as defined in claim 16 wherein said sealant material forms a chemical bond with said printed circuit board supporter.

18. A light engine made according to the process as defined in claim 16.

19. A process for manufacturing a light engine comprising:
placing the lens portion of an LED lens member into sockets located in a mold bottom;
affixing a printed circuit board with at least one LED mounted thereon and insulated wires attached thereto to a printed circuit board supporter;
placing the combination of said printed circuit with at least one LED mounted thereon and said printed circuit board supporter onto said LED lens member so that said at least one LED is located within said lens portion of said LED lens member;
placing a mold top onto said mold bottom;
injecting sealant material into spaces between said mold top and said mold bottom not occupied by said printed circuit board, said printed circuit board supporter and said LED lens member;
separating said mold top from said mold bottom;
removing said printed circuit board, said printed circuit board supporter and said lens member now partially enclosed by said sealant material from between said mold top and said mold bottom.

20. The process as defined in claim 19 wherein said printed circuit board supporter includes:
a top surface, a central portion and a bottom surface;
said top surface including mechanical placement means for positioning said printed circuit board;
said central portion including a channel for the placement of insulated wires which supply electrical energy to said printed circuit board;
said central portion further including force spreading columns constructed and arranged to apply pressure to the bottom of the printed circuit board;
said bottom surface including a contact area for receiving pressure from said mold top during the overmolding of the LED light engine.

21. A process for overmolding the components of a light engine comprising:
placing a flexible web member on a mold bottom;
affixing a printed circuit board with at least one LED mounted thereon and insulated wires attached thereto to a printed circuit board supporter;
said printed circuit board supporter including:
a top surface, a central portion and a bottom surface;
said top surface including mechanical placement means for positioning said printed circuit board;
said central portion including a channel for the placement of wires which supply electrical energy to said printed circuit board;
said central portion further including force spreading columns constructed and arranged to apply pressure to the bottom of the printed circuit board;
said bottom surface including a contact area for receiving pressure from said mold top during the overmolding of the LED light engine;
placing the combination of said printed circuit with at least one LED mounted thereon and said printed circuit board supporter onto said flexible web member so that said at least one LED is located within a hole in said flexible web member;
injecting sealant material into spaces between said mold top and said mold bottom not occupied by said printed circuit board, said printed circuit board supporter and said flexible web member;
separating said mold top from said mold bottom;
removing said printed circuit board, said printed circuit board supporter and said flexible web member now partially enclosed by said sealant material from between said mold top and said mold bottom.
